(19) United States
(12) Patent Application Publication
(10) Pub. No.: US 2004/0053080 A1
(43) Pub. Date: Mar. 18, 2004

(54) Compound film, and method for fabricating the same

(75) Inventors: Shinzo Morita, Nagoya City (JP); Masaki Matsushita, Nagoya-City (JP)

Correspondence Address: OLIFF & BERRIDGE, PLC, P.O. BOX 19928, ALEXANDRIA, VA, 22320, US

(73) Assignee: NAGOYA UNIVERSITY, Nagoya-City (JP)

(21) Appl. No.: 10/367,851

(22) Filed: Feb. 19, 2003

(30) Foreign Application Priority Data
Sep. 12, 2002 (JP) 2002-266243

(51) Int. Cl. B32B 9/04; C23C 14/32

(52) U.S. Cl. 428/704; 204/192.15; 204/192.26; 204/192.27; 204/192.28

(57) ABSTRACT

A carbon hydrogen raw material gas and a SF6 raw material gas are introduced into a chamber, and a high frequency electric power is introduced into the chamber to discharge the raw material gas to be made plasma. At the same time, a metallic plate on a main surface of one of parallel plate electrodes is sputtered to form a compound film made of carbon, sulfide and metallic elements which are dispersed in the film matrix made of carbon and sulfide and does not consititute clusters through aggregation.

### BACKGROUND OF THE INVENTION

1. Field of the Invention

This invention relates to a compound film and a method for fabricating a compound film which are preferably usable in electronic engineering field and optical engineering field.

2. Description of the Prior Art

Recently, such an attempt is made in electronic engineering field and optical engineering field as to substitute a new metallic material or an organic material on their various physical properties for a conventional material. For example, it is disclosed in European Patent Application No. 020900163 that a cupper raw material is heated within 650-700° C. under sulfide vapor of 15-20 atm including active carbon to form a compound made of carbon, sulfide and cupper which can exhibit superconductivity at a temperature of 77K.

In contrast, although a new material with high refractive index and high permeability has been developed, the physical properties can not be satisfied in electronic engineering field and optical engineering field.

### Summary of the Invention

It is an object of the present invention to provide a new material with high refractive index and high permeability.

In order to achieve the above object this invention relates to a compound film comprising at least carbon, sulfide and metallic elements which are dispersed uniformly and does not constitute clusters through aggregation.

This invention also relates to a method for fabricating a compound film, comprising the steps of:

preparing a pair of parallel plate electrodes in a chamber,

setting a substrate on a main surface of one of the electrodes which is opposite to the other electrode of the electrodes,

setting a metallic plate on a main surface of the other electrode of the electrodes so as to be opposite to the substrate, p1 introducing, in between the electrodes, at least one of a carbon hydrogen raw material gas and a hydrogen raw material gas, and a SF₆ raw material gas to be discharged and made plasma, and

applying a given voltage between the electrodes to sputter the metallic plate.

It has been reported that a compound including Au or the like has a relatively high refractive index. As more Au the compound includes, however, as more clusters Au particles constitute, so that the refractive index of the compound can not be developed much more. In contrast, the inventors paid attention to a sulfuric compound such as sulfuric glass, and then, developed a compound film with a relatively high refractive index which includes carbon and sulfide

Then, the inventors made an attempt to incorporate metallic elements in the compound film to enhance the refractive index thereof. As more metallic elements the compound includes, however, as more cluster the metallic elements constitutes through aggregation, so that the refractive index of the compound film can not be developed sufficiently.

In this point of view, the inventor intensely studied to disperse metallic elements uniformly in the compound film. As a result, they found out that if the fabricating method of the present invention as mentioned above is employed, the metallic elements can be dispersed uniformly in the compound film even at a relatively large amount. Accordingly, since the thus obtained compound film, according to the present invention, includes carbon, sulfide, and uniformly dispersed metallic elements, the refractive index and the permeability can be enhanced.

### BRIEF DESCRIPTION OF THE DRAWINGS

For better understanding of the present invention, reference is made to the attached drawings, wherein

FIG. 1 is a schematic view showing an apparatus to be employed in the fabricating method of the present invention, and

FIG. 2 is a graph showing the relation between the refractive index and the flow rate of SF₆ gas in a compound film according to the present invention.

### DESCRIPTION OF THE PREFERRED EMBODIMENTS

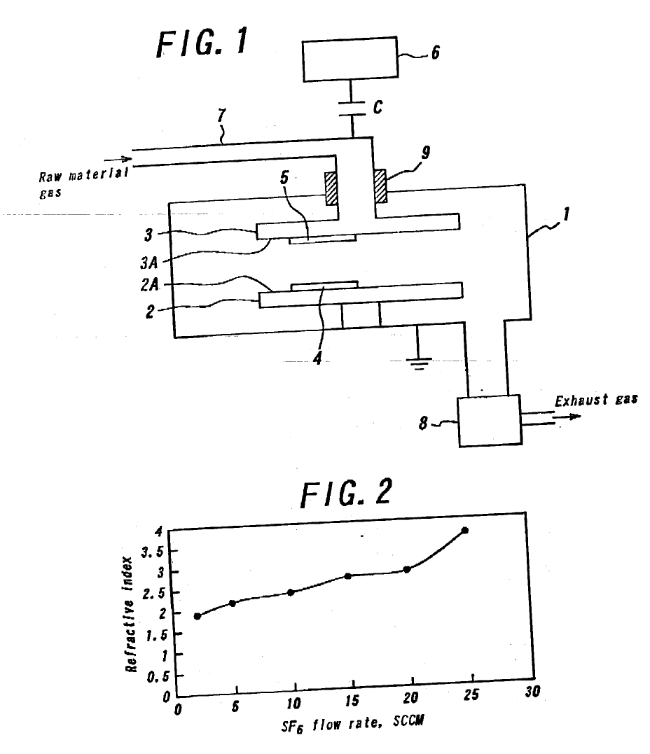

This invention will be described in detail with reference to the accompanying drawings. FIG. 1 is a schematic view showing an apparatus to be employed in the fabricating method of the present invention. In the apparatus illustrated in FIG. 1, a pair of parallel plate electrodes 2 and 3 are disposed so as to be opposite to each other in a chamber 1. A substrate 4 is placed on the main surface 2A of the electrode 2 which is opposite to the electrode 3, and a metallic plate 5 is placed on the mesh-like main surface 3A of the electrode 3 which is opposite to the electrode 2.

A gas supply path 7 is so located backward from the electrode 3 as to be held by the chamber 1 via an insulating ring 9. A carbon hydrogen raw material gas and a SF₆ law material gas are supplied into the chamber 1 from the main surface 3a of the electrode 3 through the gas supply path 7. A high frequency power supply 6 is connected 10 the chamber 1 via a condenser C. A vacuum pump 8 is provided below the clamber 1 so as to evacuate the remaining carbon hydrogen raw material gas which is not reacted to other raw material gas or the like and then, maintain the pressure inside the chamber 1 uniformly.

As mentioned above, in the apparatus illustrated in FIG. 1, the carbon hydrogen raw material gas and the SF₆ raw material gas are supplied into the chamber 1 via the main surface 3A of the electrode 3 from the gas supply path 7. Then, a high frequency electric power is supplied between the electrodes 2 and 3 from the power supply 6. In this case, the carbon hydrogen raw material gas and the SF₆ raw material gas are discharged to be made plasma. At the same time, since a given voltage is generated between the electrodes 2 and 3 by the self-biasing effect, the metallic plate 5 is sputtered.

In the plasma, the carbon hydrogen raw material gas and the SF₆ raw material gas are excited to be decomposed into their respective constituent elements. Therefore, the carbon elements of the carbon hydrogen raw material gas and the sulfide elements of the SF₆ raw material gas are deposited with the sputtered metallic elements of the metallic plate 5 on the substrate 4. As a result, a desired compound film can be obtained where the carbon elements, the sulfide elements and the metallic elements are uniformly dispersed.

In the present invention, it is desired that the flow rate ratio of the carbon hydrogen raw material gas and the SF₆ raw material gas is determined so that the ratio (hydrogen atom/fluorine atom) is set within 0.2-1.0. It is also desired that the pressure inside the chamber 1 is set within 0.1 Torr-0.01 Torr. In this case, the desired compound film can be obtained easily.

The amount of the metallic elements is preferably set to at least one atomic percentage in the compound film. In this case, the refractive index of the compound film can be enhanced much more. According to the present invention, even though the compound film includes the metallic elements of 10 atomic percentages, particularly 20 atomic percentages, the metallic elements can be uniformly dispersed in the compound film.

In this embodiment, although the carbon hydrogen raw material gas and the SF₆ raw material gas we employed, a hydrogen raw material gas may be employed, in addition to or in substitution for the carbon hydrogen raw material gas.

Although the sort of the metallic elements is not restricted, Au and Cu can be exemplified.

The compound film can exhibit a refractive index of at least 2 by utilizing a light beam with a wavelength of 628 nm. Moreover, if the fabricating condition can be selected appropriately, the compound film can exhibit a refractive index of at cast 2.6, particularly at least 3.7.

### EXAMPLE

### (Example 1)

An apparatus as shown in FIG. 1 was employed, and a compound film made of carbon, sulfide and cupper was fabricated as follows. In the apparatus as illustrated in FIG. 1, the pair of electrodes 2 and 3 were made of graphite, and the gap between the electrodes 2 and 3 was set to 1.5 cm. The glass substrate 4 was set on the main surface 2A of the electrode 2, and the cupper plate 5 with a size of 50×50 mm² was set on the main surface 3A of the electrode 3. Then, a CH₄ raw material gas, a SH₆ raw material gas and an Ar carrier gas were introduced into the chamber 1. The flow rates of the CH₄ raw material gas and the Ar raw carrier gas were set to 10 sccm, respectively, and the flow rate of the SF₆ raw material gas was varied within 2-25 sccm. The pressure inside the chamber 1 was set to 0.1 Torr.

Then, a high frequency electric power with an electric power of 100W and a frequency of 13.56 MHz was introduced into the chamber 1 to discharge the CH₄ raw material gas, the SF₆ raw material gas and the Ar carrier gas and sputter the cupper plate 5 for 30 minutes. Thereafter, it was turned out that a yellow transparent film was made on the substrate 4. When the film was measured by means of ESCA, it was turned out that the cupper elements were dispersed uniformly in a film matrix made of carbon and sulfide. Therefore, it was turned out that a compound film made of carbon, sulfide and cupper uniformly dispersed was made through the above fabricating process. The refractive index of the compound film exhibited a maximum value of 2.6 when the flow rate of the SF₆ raw material gas was set to 25 sccm.

### (Example 2)

Except that an Au plate was set on the main surface 3A of the electrode 3, in substitution for the cupper plate, the discharging process and the sputtering process were carried out in the same manner as Example 1. As a result, a transparent film was made on the glass substrate, and when the film was measured by means of ESCA, it was turned out that Au elements were dispersed uniformly in a film matrix made of carbon and sulfide. In this case, therefore, it was turned out that a compound film made of carbon, sulfide and cupper was made through the above fabricating, process.

FIG. 2 is a graph showing the relation between the refractive index and the flow rate of the SF₆ raw material gas in the compound film. As is apparent from FIG. 2, the refractive index of the compound film is increased as the flow rate of the SF₆ law material gas is increased, and then, the refractive index of the compound film is about 3.7 when the flow rate of the SF₆, raw material gas is set to 25 sccm.

Accordingly, it is turned out from Examples 1 and 2 that the thus obtained compound film is transparent and thus, is promising as a new optical material.

Although the present invention was described in detail with reference to the above examples, this invention is not limited to the above disclosure and every kind of variation and modification may be made without departing from the scope of the present invention.

Although in the above embodiments, the metallic plate 5 was set on the main surface 3A of the electrode 3, and sputtered to form a compound film including the metallic elements, another compound film including other elements can be formed if an insulating film or the like was set.

As is explained above, a new material with a high refractive index and a high permeability can be provided.

What is claimed is:

1. A compound film comprising at least carbon, sulfide and metallic elements which are dispersed uniformly and does not constitute clusters through aggregation.

2. The compound film as defined in claim 1, wherein said metallic elements are Au elements.

3. The compound film as defined in claim 1, wherein said metallic elements are Cu elements.

4. The compound film as defined in claim 1, wherein the content of said metallic elements is set to at least one atomic percentage.

5. The compound film as defined in claim 1, comprising a refractive index of at least two by a light beam with a wavelength of 628 nm.

6. The compound film as defined in claim 5, comprising a refractive index of at least 2.6 by a light beam with a wavelength of 628 nm.

7. A method for fabricating a compound film, comprising the steps of:
preparing a pair of parallel plate electrodes in a chamber,
setting a substrate on a main surface of one of said electrodes which is opposite to the other electrode of said electrodes,
setting a metallic plate on a main surface of the other electrode of said electrodes so as to be opposite to said substrate,
introducing, in between said electrodes, at least one of a carbon hydrogen raw material gas and a hydrogen raw material gas, and a SF₆ raw material gas to be discharged and made plasma, and
applying a given voltage between said electrodes to sputter said metallic plate.

8. The fabricating method as defined in claim 7, wherein the discharging process for said raw material gases and the sputtering process for said metallic plate are carried out simultaneously.

9. The fabricating method as defined in claim 7, wherein the flow rate ratio of said carbon hydrogen raw material gas and said SF₆ raw material gas is determined so that the ratio (hydrogen atom/fluorine atom) is set within 0.2-1.0.

10. The fabricating method as defined in claim 7, wherein the pressure inside said chamber is set within 0.1-0.01 Torr.
